(19) United States
(12) Patent Application Publication
(10) Pub. No.: US 2021/0234332 A1
(43) Pub. Date: Jul. 29, 2021

(54) Optical Transmitter and Multi-Wavelength Optical Transmitter

(71) Applicant: Nippon Telegraph and Telephone Corporation, Tokyo (JP)

(72) Inventors: Takahiko Shindo, Musashino-shi, Tokyo (JP); Naoki Fujiwara, Musashino-shi, Tokyo (JP); Hiroyuki Ishii, Musashino-shi, Tokyo (JP)

(21) Appl. No.: 15/734,649

(22) PCT Filed: May 23, 2019
(86) PCT No.: PCT/JP2019/020458

§ 371 Date: Dec. 3, 2020

(30) Foreign Application Priority Data
Jun. 5, 2018 (JP) 2018-107696
Nov. 12, 2018 (JP) 2018-212353

(51) Int. Cl. H01S 5/026; H01S 5/125; H01S 5/042; H01S 5/40

(52) U.S. Cl. CPC H01S 5/026; H01S 5/4087; H01S 5/04256; H01S 5/125

(57) ABSTRACT

There is provided an optical transmitter having high optical feedback resistance even at the time of high-output operation and capable of suppressing deterioration of optical waveform quality and transmission characteristics. The optical transmitter includes a DBR laser, an EA modulator, a passive optical waveguide, and an SOA that are monolithically integrated on a same substrate, the DBR laser including an active region where current is injected and optical gain is obtained, and two DBR regions that are formed on opposite ends of the active region, the EA modulator optically modulating laser light from the DBR laser, the passive optical waveguide being for guiding modulated light from the EA modulator, the SOA optically amplifying the modulated light from the passive optical waveguide.

### TECHNICAL FIELD

The present invention relates to an optical transmitter that uses a semiconductor laser element where an optical modulator is integrated, and a multi-wavelength optical transmitter. More specifically, the present invention relates, for example, to an optical transmitter that uses a semiconductor laser element including an electro-absorption (EA) optical modulator, a semiconductor optical amplifier (SOA) and a distributed Bragg reflector (DBR) laser that are integrated on an InP substrate, and a multi-wavelength optical transmitter.

### BACKGROUND ART

These days, with the spread of video distribution services and growing demand for mobile traffic, network traffic is increasing rapidly, and active discussion is being held concerning next-generation networks, particularly in relation to network regions called access systems. With regard to such next-generation access-system networks, there is a trend to demand for an increased transmission distance and higher splitting, and to cover an increase in a splitting ratio, there is also increasing demand to realize high optical output in relation to a semiconductor modulation light source that is used.

(Conventional EADFB Laser)

Because an electro-absorption modulator integrated DFB (EADFB) laser having an electro-absorption (EA) optical modulator integrated with a distributed feedback (DFB) laser achieves higher extinction characteristics and superior chirp characteristics compared with a direct modulation laser, the electro-absorption modulator integrated DFB laser has been widely used, including in an access-system network light source.

FIG. 1 shows a schematic diagram of a substrate cross-section, along an optical axis, of a conventional general EADFB laser 10. The EADFB laser 10 in FIG. 1 has a structure where a DFB laser 11 and an EA modulator 12 are integrated in a same chip along an optical waveguide that is an optical axis. The DFB laser 11 includes an active layer 14 of multi-quantum well (MQW), and is caused to oscillate at a single wavelength by a diffraction grating 17 formed on the active layer 14 in a resonator. Moreover, the EA modulator 12 includes a light absorption layer 15 of multi-quantum well (MQW) of composition different from that of the DFB laser, and a light absorption amount may be changed through voltage control. Light is caused to blink by driving the EA modulator 12 by a modulation electric signal under conditions for transmitting/absorbing output light from the DFB laser 11, and an electric signal is converted into an optical signal and light is emitted from a right end.

A problem of the EADFB laser is that, because light absorption at the EA modulator is used for optical modulation, there is a relationship of trade-off between higher optical output and extinction characteristics that are sufficient in principle.

FIG. 2 shows a schematic diagram of an extinction curve and an intensity modulation principle of the conventional general EADFB laser. With the conventional general EADFB laser, when an absolute value of a reverse applied voltage to the EA modulator is increased, an extinction ratio is reduced, and when a modulation voltage of predetermined amplitude Vpp is superimposed on a predetermined EA reverse applied voltage (bias voltage) Vdc and applied, a predetermined dynamic extinction ratio DER is obtained.

With the general EADFB laser, one method of achieving higher output is to reduce the absolute value of the reverse applied voltage to the EA modulator, and to suppress light absorption at the EA modulator. However, in this case, steepness of the extinction curve of the EA modulator is reduced, causing modulation characteristics, or in other words, the dynamic extinction ratio (DER), to deteriorate.

As another method for achieving higher output, there is a method of increasing a drive current to the DFB laser, and increasing intensity of light entering the EA modulator from the DFB laser. However, according to this method, power consumption of the DFB laser is increased, and also, the extinction characteristics deteriorate due to light absorption at the EA modulator and an increase in a photocurrent caused by the light absorption, and power consumption of the entire chip is increased. Accordingly, with the conventional EADFB laser, an excessive increase in the power consumption is unavoidable to achieve both sufficient optical output and sufficient modulation characteristics (dynamic extinction ratio).

In response to such a problem, there is proposed a semiconductor optical amplifier (SOA)-integrated EADFB laser, according to which a semiconductor optical amplifier (SOA) is further integrated at a light emission end of the EADFB laser (Non-Patent Literature 1).

(Conventional SOA-Integrated EADFB Laser)

FIG. 3 shows a schematic diagram of a substrate cross-section, along an optical axis, of a conventional SOA-integrated EADFB laser 30. The SOA-integrated EADFB laser 30 in FIG. 3 has a structure where a DFB laser 31, an EA modulator 32, and an SOA region 33 are integrated in this order in a same chip, along an optical waveguide that is an optical axis.

The DFB laser 31 includes an active layer 34 including a diffraction grating as shown in FIG. 1, the EA modulator 32 includes an active layer 35, and the SOA region 33 includes an active layer 36, and normally, the active layers 34 and 36 are of same MQW, and the active layer 35 of the EA modulator 32 is of another MQW structure.

With the SOA-integrated EADFB laser 30, signal light obtained by modulating laser light from the DFB laser 31 by the EA modulator 32 is amplified in the integrated SOA region 33, independently of the EA modulator 32, and thus, optical output may be increased without reducing quality of an optical signal waveform.

Furthermore, compared with the conventional EADFB laser, the SOA-integrated EADFB laser 30 is capable of achieving higher output without excessively increasing a drive current to the DFB laser 31 or a photocurrent of the EA modulator 32. Furthermore, with the SOA-integrated EADFB laser, the active layer 36 of the SOA 33 has a same MQW structure as the active layer 34 of the DFB laser 31. Accordingly, a regrowth process for integration of the SOA region 33 does not have to be added at the time of element fabrication, and device fabrication by same manufacturing steps as for the conventional EADFB laser is possible.

Such an SOA-integrated EADFB laser may also be used for an arrayed multi-wavelength light source that simultaneously uses, for communication, light of a plurality of wavelengths to achieve high capacity, and that is necessary for a multi-wavelength optical transmitter for wavelength division multiplexing (WDM).

### CITATION LIST

### Non-Patent Literature

Non-Patent Literature 1: W Kobayashi et al., “Novel approach for chirp and output power compensation applied to a 40-Gbit/s EADFB laser integrated with a short SOA,” Opt. Express, Vol. 23, No. 7, pp. 9533-9542, April 2015

### SUMMARY OF THE INVENTION

### Technical Problem

The conventional SOA-integrated EADFB laser has a problem that reflected optical feedback returning into the element from an emission end face or a reflection point outside the element at the time of high-output operation destabilizes operation of the DFB laser. A general EADFB laser is applied with an anti-reflection (AR) coating to suppress light reflection from the emission end face, and reflected optical feedback from the end face into the chip is generally suppressed to 0.1% or less. Moreover, in a case where the EADFB laser is used as an optical transmitter, an optical isolator is used on a light output side, and reflected optical feedback that is propagated through an optical fiber over a long distance is also greatly suppressed.

However, in the case of the SOA-integrated EADFB laser, due to high-output characteristics, even a small amount of reflected optical feedback greatly affects performance characteristics. If an optical amplification effect of the SOA of the SOA-integrated EADFB laser is +3 dB compared to the conventional EADFB laser, average optical output is increased by +3 dB, and also, reflected optical feedback intensity is increased by 3 dB. Moreover, because the reflected optical feedback from the end face is amplified again inside the SOA, the reflected optical feedback intensity at a DFB laser unit is increased by +6 dB compared to the EADFB laser.

Generally, a semiconductor laser performs laser oscillation by positive feedback of light by internal reflection and amplification of light by stimulated emission from the active layer. When optical feedback enters from outside the element, the optical feedback is amplified by stimulated emission and an oscillation state is greatly disturbed, and noise in laser oscillation light is greatly increased. This noise is generally referred to as optical feedback-induced noise.

Furthermore, in the case of the SOA-integrated EADFB laser, light that returns into the element from an end face of the element is a part of signal light that is subjected to intensity modulation at the EA modulator. Accordingly, intensity of the reflected optical feedback varies at a same bit rate as the signal light. The optical feedback reaches the DFB laser after being subjected again to intensity modulation at the EA modulator. Accordingly, intensity of the optical feedback reaching the DFB laser is varied in a complex manner, and oscillation state of the DFB laser is thus greatly varied over time.

In the case where operation of the DFB laser becomes unstable, quality of an optical signal waveform modulated by the EA modulator and transmission characteristics deteriorate. As described above, the optical feedback intensity increases depending on the optical output intensity of the SOA-integrated EADFB laser, and thus, the transmission characteristics greatly deteriorate especially at the time of high-output operation of the SOA-integrated EADFB laser.

Due to such circumstances, an arrayed multi-wavelength light source that is used in a multi-wavelength optical transmitter for WDM has a problem that, because the state of optical feedback is different depending on the wavelength, and characteristics of the element are also changed, it is difficult to generate light of a plurality of different wavelengths at uniform optical output intensity.

The present invention has been made in view of such problems, and is aimed at providing an optical transmitter having high optical feedback resistance even at the time of high-output operation and capable of suppressing deterioration of optical waveform quality and transmission characteristics, and at achieving uniform optical output intensity in relation to an arrayed multi-wavelength light source of a multi-wavelength optical transmitter.

### Means for Solving the Problem

To solve the problems described above, an aspect of the present invention introduces a distributed Bragg reflector (DBR) laser, instead of the DFB laser of the SOA-integrated EADFB laser. The DBR laser includes an active region where optical gain is obtained by current injection, and two Bragg reflectors (DBR) that are disposed on opposite ends, on an optical axis, of the active region and that serve as reflection mirrors. The DBR laser does not include a diffraction grating in the active region. As in the case of the SOA-integrated EADFB laser, output light from a DBR laser light source is modulated by an EA modulator, amplified by an SOA, and is then emitted from an emission end face. However, optical feedback is reflected by a DBR region on an emission side, and the optical feedback reaching the active region of the DBR laser is reduced, and thus, influence of the optical feedback on the active region of the DBR laser is reduced. Accordingly, with an SOA-integrated EADBR laser according to the aspect of the present invention, an optical transmitter where regions are monolithically integrated along an optical axis, in the order of the DBR, the active region, the DBR, the EA modulator, and the SOA, is obtained, and high optical feedback resistance is achieved.

The present invention has the following configurations.

(Configuration 1)

An optical transmitter, including:
a DBR laser including an active region where current is injected and optical gain is obtained, and two DBR regions that are formed on opposite ends of the active region;
an EA modulator optically modulating laser light from the DBR laser; and
an SOA optically amplifying modulated light from the EA modulator,
wherein the DBR laser, the EA modulator, and the SOA are monolithically integrated on a same substrate.

(Configuration 2)

The optical transmitter according to Configuration 1, wherein a passive optical waveguide for guiding the modulated light from the EA modulator is provided between the EA modulator and the SOA.

(Configuration 3)

The optical transmitter according to Configuration 2, wherein an electrode is formed on the passive optical waveguide, the electrode being for monitoring the modulated light guided in the passive optical waveguide.

(Configuration 4)

The optical transmitter according to any one of Configurations 1 to 3, wherein current is injected into the active region of the DBR laser and the SOA by a same control terminal.

(Configuration 5)

The optical transmitter according to any one of Configurations 1 to 4, wherein electrodes are formed on the two DBR regions, and the electrodes are grounded.

(Configuration 6)

multi-wavelength optical transmitter including:
a plurality of optical transmitters according to any one of Configurations 1 to 5, the plurality of optical transmitters having different oscillation wavelengths; and
a multiplexer for multiplexing output light from the optical transmitters, wherein
intensity of output light of all the optical transmitters are made uniform by making a length of at least one of the active region and the SOA of at least one of the plurality of optical transmitters on a short-wavelength side longer than those of other optical transmitters.

(Configuration 7)

A multi-wavelength optical transmitter including:
a plurality of optical transmitters according to any one of Configurations 1 to 5, the plurality of optical transmitters having different oscillation wavelengths; and
a multiplexer for multiplexing output light from the optical transmitters, wherein
intensity of output light of all the optical transmitters are made uniform by making a front-rear ratio of lengths of the two DBR regions of at least one of the plurality of optical transmitters on a short-wavelength side smaller than those of other optical transmitters.

(Configuration 8)

The optical transmitter according to any one of Configurations 1 to 5, wherein diffraction grating periods of the two DBR regions included in the DBR laser are different from each other.

(Configuration 9)

The optical transmitter according to Configuration 8, wherein
diffraction gratings of the two DBR regions included in the DBR laser have a same refractive index coupling coefficient, and
the refractive index coupling coefficient takes a value in a range of 40 cm⁻¹ to 100 cm⁻¹.

(Configuration 10)

The optical transmitter according to Configuration 9, wherein,
when, of DBRs of the two DBR regions, a DBR present between the active region of the DBR laser and the EA modulator is taken as a first DBR, and another DBR is taken as a second DBR,
a wavelength difference between a Bragg wavelength of the first DBR and a Bragg wavelength of the second DBR is half or less of a bandwidth of a stopband of the first DBR.

### Effects of the Invention

As described above, the present invention may provide an optical transmitter having high optical feedback resistance even at a time of high-output operation, and capable of suppressing deterioration of optical waveform quality and transmission characteristics.

### BRIEF DESCRIPTION OF DRAWINGS

FIG. 1 is a schematic diagram of a substrate cross-section, along an optical axis, of a conventional EADFB laser.

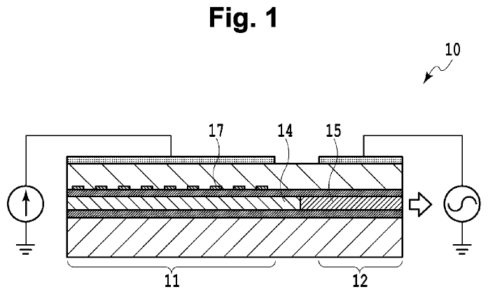

FIG. 2 is a schematic diagram of an extinction curve and an intensity modulation principle of the conventional EADFB laser.

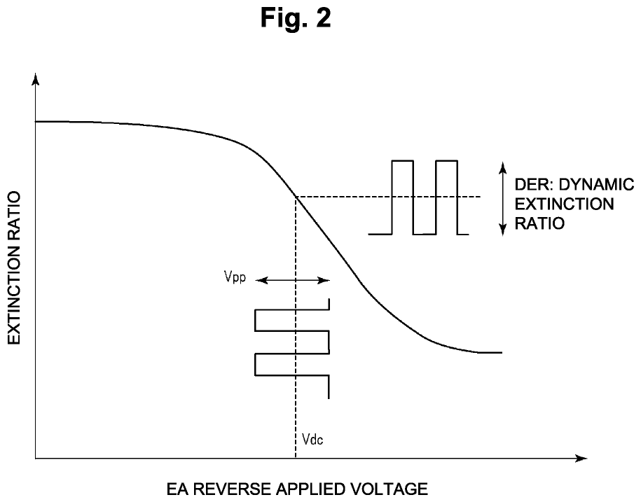

FIG. 3 is a schematic diagram of a substrate cross-section of a conventional SOA-integrated EADFB laser.

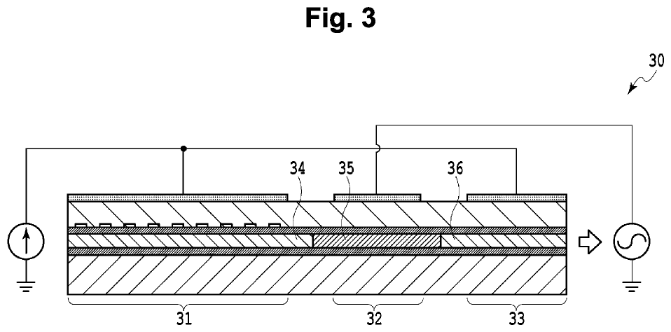

FIG. 4 is a substrate cross-section diagram of an SOA-integrated EADBR laser of an optical transmitter according to Embodiment 1 of the present invention.

FIG. 5(a) is a diagram showing an eye pattern of the SOA-integrated EADBR laser according to the present invention, and FIG. 5(b) is a diagram showing an eye pattern of a conventional SOA-integrated EADFB laser.

FIG. 6 is a substrate cross-section diagram of Modification 1 of Embodiment 1 of the present invention.

FIG. 7 is a substrate cross-section diagram of Modification 2 of Embodiment 1 of the present invention.

FIG. 8 is a substrate cross-section diagram of Modification 3 of Embodiment 1 of the present invention.

FIG. 9 is a schematic plan view of a multi-wavelength light source provided with a plurality of SOA-integrated EADBR lasers according to Embodiment 2 of the present invention.

FIG. 10 is a schematic plan view of Modification 1 of Embodiment 2 of the present invention.

FIG. 11 is a schematic plan view of Modification 2 of Embodiment 2 of the present invention.

FIGS. 12(a) to 12(c) are diagrams for describing an object of Embodiment 3 of the present invention.

FIGS. 13(a) and 13(b) are diagrams for describing the object of Embodiment 3 of the present invention.

FIGS. 14(a) and 14(b) are diagrams for describing the object of Embodiment 3 of the present invention.

FIG. 15 is a diagram for describing the object of Embodiment 3 of the present invention.

FIGS. 16(a) to 16(d) are diagrams for describing Embodiment 3 of the present invention.

FIG. 17 is a diagram for describing Embodiment 3 of the present invention.

FIGS. 18(a) and 18(b) are diagrams for describing Embodiment 3 of the present invention.

FIG. 19 is a substrate cross-section diagram for describing Embodiment 3 of the present invention.

### DESCRIPTION OF EMBODIMENTS

Hereinafter, embodiments of the present invention will be described in detail with reference to the drawings.

First, an oscillation principle of a DBR laser used in the present invention will be described. The DBR laser includes DBR regions on opposite ends of an active region, where a diffraction grating is formed on each DBR region. With the DBR laser, unlike a DFB laser, a diffraction grating is not formed in the active region. The DBR region selectively reflects only a specific wavelength corresponding to a period of the diffraction grating. Accordingly, an optical resonator is formed by the DBR regions on opposite ends of the active region to provide positive feedback of light, and oscillation only at a specific wavelength may be achieved.

The DBR laser has a structure where an active region having an optical amplification effect based on stimulated emission is sandwiched between two front and rear DBR regions on an optical axis. Accordingly, reflected optical feedback returning into an element from an emission end face passes through the DBR region before reaching the active region. The reflected optical feedback originates from oscillation light from the DBR laser, and thus, has a wavelength that inevitably coincides with a reflection band of the DBR. Accordingly, the optical feedback is reflected according to reflectance of the DBR, and thus, intensity of optical feedback reaching the active region may be reduced.

On the other hand, with the DFB laser used in the conventional SOA-integrated EADFB laser, the diffraction grating is formed in the active region. Also in the case of the DFB laser, the optical feedback is reflected by the diffraction grating, but the optical feedback is propagated while being amplified as it enters the laser, and laser characteristics are greatly affected. For the reasons stated above, the DBR laser has higher optical feedback resistance than the DFB laser, and is able to suppress deterioration of optical waveform quality and transmission characteristics.

### Embodiment 1

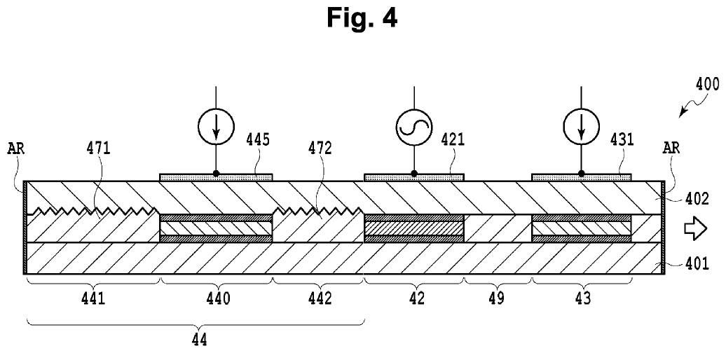

FIG. 4 is a substrate cross-section diagram, along an optical axis, of an SOA-integrated EADBR laser 400 of an optical transmitter according to Embodiment 1 of the present invention. With the SOA-integrated EADBR laser 400 of the optical transmitter according to Embodiment 1 shown in FIG. 4, a DBR laser 44, an EA modulator 42, a passive waveguide 49, and an SOA 43 are monolithically integrated on a same n-InP substrate 401 in this order from the left, along an optical waveguide as an optical axis of laser light. The DBR laser 44, the EA modulator 42, and the SOA 43 are driven, respectively, through electrodes 445, 421, and 431 provided on a p-InP cladding layer 402, and modulated laser light is thus emitted from a right end.

The DBR laser 44 includes an active region 440, and DBR regions 441, 442 on left and right ends of the active region 440, the DBR regions 441, 442 including diffraction gratings 471, 472. A length of the active region 440 is 300 μm, a length of the DBR region 442 (on a right-end emission side, on the EA modulator 42 side) is 200 μm, and a length of the DBR region 441 (on a left-end reflection side) is 400 μm.

Furthermore, the EA modulator 42 having a length of 150 μm, the passive waveguide 49 having a length of 50 μm, and the SOA 43 having a length of 100 μm are integrated on the right-end emission side of the DBR laser 44 to form a monolithically integrated element.

(Fabrication Process of Element of Present Invention)

Here, an element fabrication process for the SOA-integrated EADBR laser 400 of the optical transmitter of Embodiment 1 will be described. In element fabrication, an initial substrate where a lower separated confinement heterostructure (SCH) layer, an active layer of a multi-quantum well layer (MQW1), and an upper SCH layer are sequentially grown on the n-InP substrate 401 is used. The multi-quantum well layer (MQW1) has an optical gain in an oscillation wavelength of 1.3 μm band. The n-InP substrate 401 functions also as a cladding layer.

First, parts that are to be the active region 440 of the DBR laser 44 and the SOA region 43 are kept, and rest of the active layer (MQW1) is selectively etched, and a multi-quantum well layer (MQW2) for the EA modulator 42 is formed by butt-joint regrowth. Subsequently, selective etching and butt-joint regrowth are performed again while keeping parts that are to be the active region 440 of the DBR laser, the EA modulator region 42, and the SOA region 43, and a core layer of the passive waveguide 49 and other optical waveguides is thereby formed.

Next, the diffraction gratings 471, 472 that operate at the oscillation wavelength of 1.3 μm band are formed on parts, of the core layer of optical waveguides that is formed, that are to be the DBR regions 441, 442. Then, the p-InP cladding layer 402 is formed on an entire surface of the element by regrowth. A thickness of the p-InP cladding layer 402 is designed such that a light field does not overlap an electrode region, and is 2.0 μm in Embodiment 1.

Next, a mesa structure is formed by etching, and a semi-insulating InP layer (not shown) where Fe is doped on both sides of the mesa is formed by buried regrowth. Next, p-side electrodes 445, 421, 431 are formed on an upper surface of the semiconductor substrate. Then, the n-InP substrate 401 is polished to about 150 μm, an electrode (not shown) is formed on a back surface of the substrate, and steps on an upper part of a semiconductor wafer are completed. Additionally, anti-reflection coatings (AR) are applied on both left and right end faces of the substrate.

Regarding a vertical direction of the resonator, a waveguide structure of the present embodiment has a laminated structure including a core layer including the active layers (MQW1, 2) of multi-quantum well and the upper and lower SCH layers (a total layer thickness of 200 nm), and the InP cladding layers 401, 402 sandwiching the core layer from above and below. Regarding a horizontal direction, the waveguide structure of the present embodiment has a buried heterostructure where InP layers are formed on both sides of the mesa. Moreover, a stripe width is 1.5 μm, and operation is performed at a single wavelength due to the diffraction gratings formed in the DBR regions.

Furthermore, regarding the part of the SOA 43, the core layer structure formed in the initial growth substrate is kept as it is, and the part has a same layer structure (MQW1) as that of the active region 440 of the DBR laser 44. Moreover, the DBR regions 441, 442 and the passive waveguide region 49 have the same core layer formed in the butt-joint growth, and the only difference in the layer structures of these regions are whether the diffraction gratings 471, 472 are present or not. Accordingly, even with the structure where a plurality of regions are integrated, the number of times of regrowth may be suppressed, and fabrication at a low cost is enabled.

By providing the passive waveguide 49 between the EA modulator 42 and the SOA 43, insulation between the SOA where forward bias is applied and the EA where reverse bias is applied may be increased. In a case where the passive waveguide 49 is not provided, separation resistance between upper electrodes of the EA modulator 42 and the SOA 43 is 1 kΩ or less. In contrast, when the passive waveguide 49 having a length of 50 μm is inserted, separation resistance is increased to about 50 kΩ, and electrical crosstalk between the regions may be reduced.

(Evaluation of Modulation Characteristics of Element of Present Invention)

Modulation characteristics at 25 Gbit/s was evaluated using an element fabricated according to the present invention. Evaluation was also performed under same conditions for the conventional SOA-integrated EADFB laser fabricated on the same substrate, and the effects of the present invention were examined. As a modulation signal, an NRZ pseudo-random signal (PRBS) at 2³¹−1 stage cycle was used, and a bias voltage to the EA modulator was 1.5 V, and an amplitude voltage was 2.0 V. Furthermore, a chip temperature was set to 45 degrees C. First, optical output characteristics at the time of modulation were compared, and approximately same optical output intensity was obtained with the optical intensity when a fiber was coupled being 6.0 dBm for the SOA-integrated EADBR laser and 6.1 dBm for the SOA-integrated EADFB laser. Here, currents at 90 mA and 30 mA were injected to the laser unit and the SOA unit of both elements.

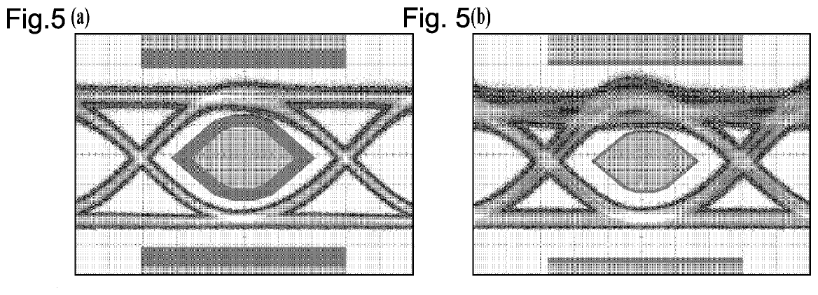

FIG. 5 shows an eye pattern (a) of the SOA-integrated EADBR laser according to the embodiment of the present invention, and an eye pattern (b) of the conventional SOA-integrated EADFB laser that is shown for comparison. In either case, an eye pattern at a bit rate of 25 Gbit/s and in an NRZ non-modulated, back-to-back (BTB) state is shown. With the conventional SOA-integrated EADFB laser in FIG. 5(b), an optical waveform is distorted, and sufficient eye opening is not obtained. In contrast, with the SOA-integrated EADBR laser of the embodiment of the present invention shown in FIG. 5(a), deterioration of eye pattern quality is suppressed also at the time of high optical output, and a clear eye opening is obtained.

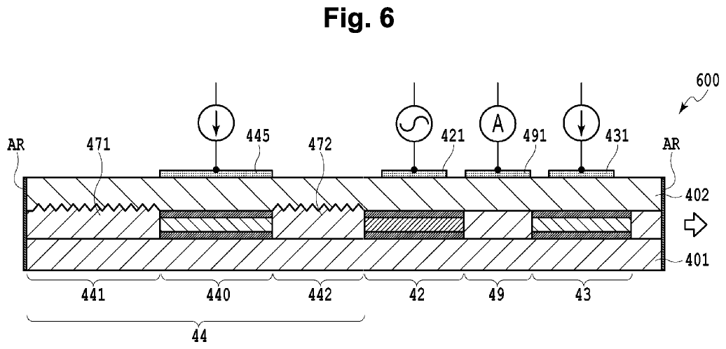

As in the case of an SOA-integrated EADBR laser 600 of Modification 1 of Embodiment 1 of the present invention shown in FIG. 6, intensity of output light may be monitored by providing an electrode 491 on the passive waveguide part 49 provided between the EA modulator 42 and the SOA region 43, and by monitoring a current value of the electrode 491.

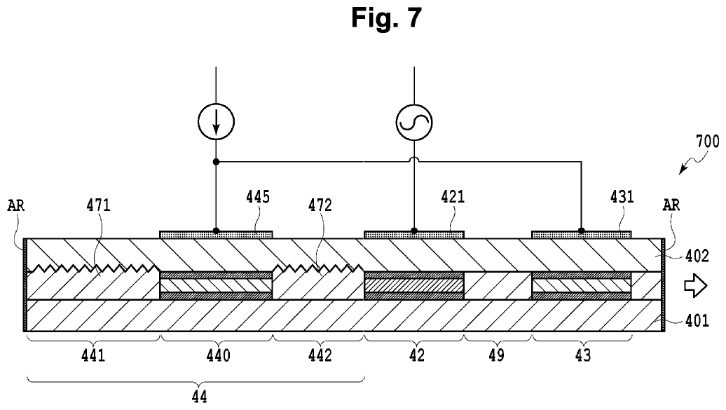

Furthermore, as in the case of an SOA-integrated EADBR laser 700 of Modification 2 of Embodiment 1 of the present invention shown in FIG. 7, the number of terminals may be reduced by commonly driving the active region 440 of the DBR laser 44 and the SOA region 43 with a same bias direction.

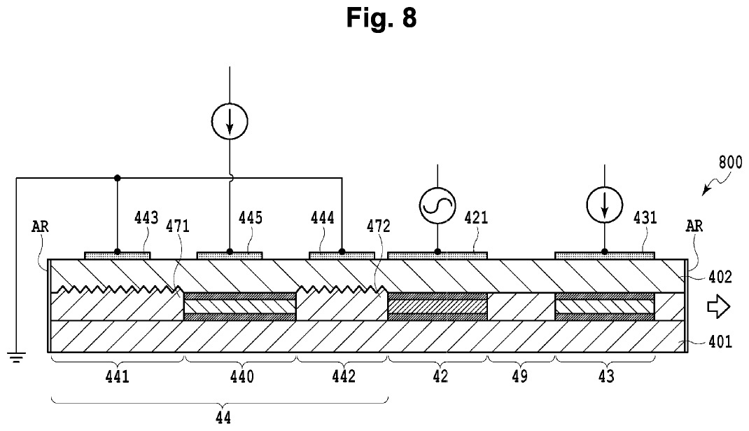

Furthermore, as in the case of an SOA-integrated EADBR laser 800 of Modification 3 of Embodiment 1 of the present invention shown in FIG. 8, by grounding the DBR regions 441, 442 of the DBR laser 44 via electrodes 443, 444, a shift in Bragg wavelengths of the DBR regions due to a current leakage from the active region 440 may be suppressed, and a reduction in an optical feedback suppression effect may be prevented.

### Embodiment 2

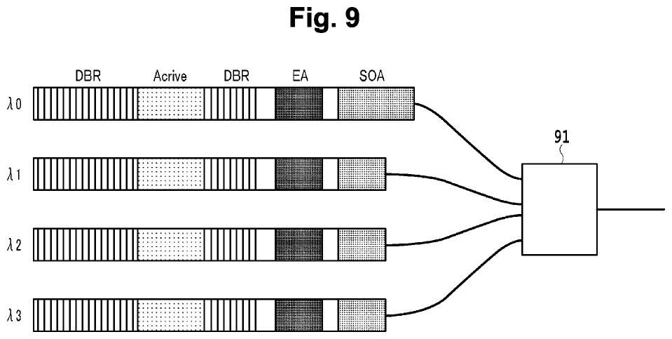

FIG. 9 shows, in relation to a multi-wavelength optical transmitter of Embodiment 2 of the present invention, a schematic plan view of an arrayed multi-wavelength light source that is provided with a plurality of SOA-integrated EADBR lasers. In FIG. 9, SOA-integrated EADBR lasers corresponding to respective wavelengths λ0, λ1, λ2, λ3 are provided, each SOA-integrated EADBR laser having a structure as described in Embodiment 1. Laser light at each wavelength is modulated by the EA modulator, and is output after being optically amplified by the SOA. Regarding the oscillation wavelengths λ0, λ1, λ2, λ3 of output light, λ0<λ1<λ2<λ3 is true, and the output light is output after being multiplexed by a multiplexer 91 on a right end.

With such an arrayed multi-wavelength light source, optical output of the SOA-integrated EADBR laser of the wavelength XO, which is the shortest wavelength, is reduced due to light being absorbed even when the EA modulator is in an ON state. Accordingly, as shown in FIG. 9, with the arrayed multi-wavelength light source of Embodiment 2 of the present invention, the reduction in the optical output is compensated for by making an SOA length for the wavelength λ0 150 μm, which is longer than for other wavelengths (the SOA lengths are 100 μm for other wavelengths). As a result, optical output intensity at the wavelength λ0 may be increased by 1 dB, and intensity of output light from the multiplexer 91 may be made uniform for all the wavelengths.

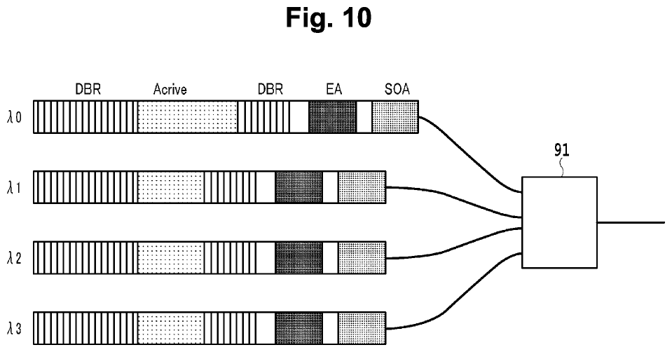

For the same purpose, in Modification 1 of Embodiment 2 of the present invention shown in FIG. 10, a length of the active region (Active) is made 400 μm for only the SOA-integrated EADBR laser that oscillates at XO, and the length is longer than for other wavelengths (the lengths are 300 μm for other wavelengths). As a result, the optical output intensity at the wavelength λ0 may be increased by 1 dB, and intensity of output light from the multiplexer 91 may be made uniform for all the wavelengths.

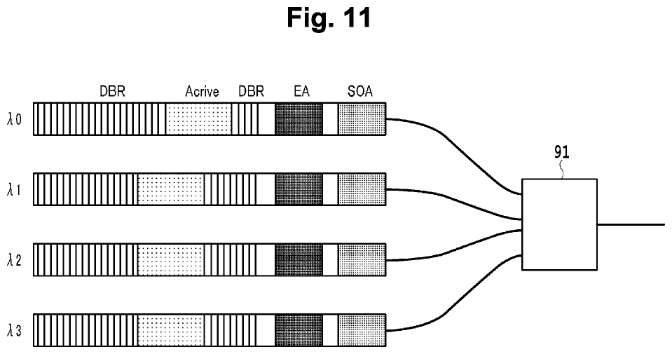

In Modification 2 of Embodiment 2 of the present invention shown in FIG. 11, lengths of two DBR regions are 500 μm for the rear DBR region (left-end reflection side) and 100 μm for the front DBR region (right-end emission side) only for the SOA-integrated EADBR laser that oscillates at λ0, and a front-rear ratio of the lengths of the two DBRs (front-rear values) is made smaller than for other wavelengths (the rear DBR region is 400 μm and the front DBR region is 200 μm for other wavelengths). As a result, the optical output intensity on a front side of the DBR laser may be increased by 1 dB, and intensity of output light from the multiplexer may be made uniform for all the wavelengths.

### Embodiment 3

### Description of Object of Embodiment 3

To further increase reflected optical feedback resistance of the SOA-integrated EADBR laser described above, reflectance of the DBR region (front DBR) present between the active region of the DBR laser and the EA modulator has to be increased. The optical feedback resistance may be increased by increasing the reflectance of the front DBR and reducing intensity of the optical feedback entering the active region from an incident end face.

However, if DBR reflectance of the DBR laser is simply increased, there is a concern that single mode characteristics of the DBR laser deteriorate, causing oscillation likely to occur in a multi-mode. Generally, to increase the reflectance of the DBR, there are a method of increasing a refractive index coupling coefficient κ of the diffraction grating, and a method of increasing a DBR region length. The refractive index coupling coefficient of the diffraction grating is one parameter indicating an influence of coupling of a traveling wave inside the diffraction grating and a backward wave generated by reflection. Generally, the coupling coefficient is increased, the greater the diffraction grating depth and the greater the change in the refractive index. Moreover, generally, maximum reflectance and a reflection band of the DBR region are increased, the greater the refractive index coupling coefficient, and a reflection mirror having a wider band and higher reflectance may thereby be achieved.

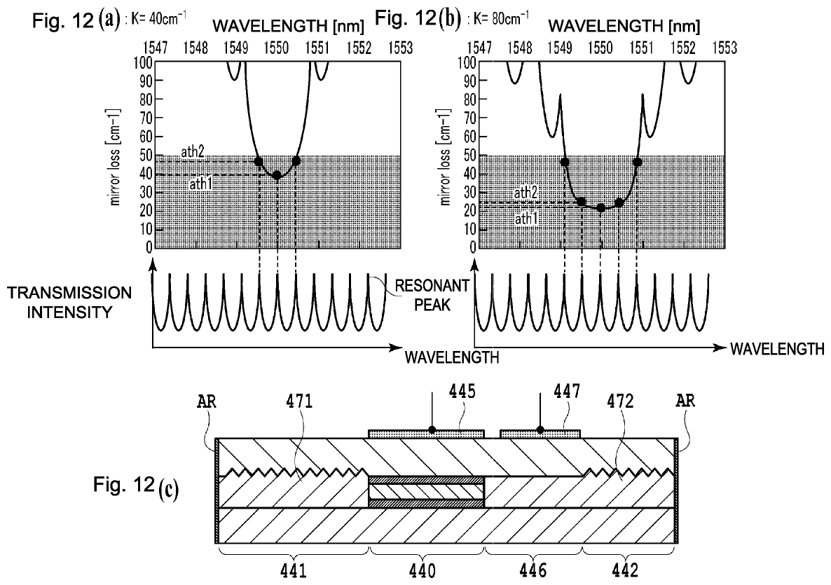

FIGS. 12(a) and 12(b) are for comparing wavelength dependence of a mirror loss (mirror loss on vertical axes) between DBR lasers, as shown in FIG. 12(c), having a same structure but with different refractive index coupling coefficients κ, with κ being 40 cm⁻¹ in FIG. 12(a) and 80 cm⁻¹ in FIG. 12(b).

Generally, the diffraction gratings of the front and rear DBR regions of the DBR laser are collectively fabricated in a same process. Accordingly, the refractive index coupling coefficient κ takes a same value for the front and rear DBRs. Here, as shown in a substrate cross-section diagram in FIG. 12(c), a length of the DBR region 442 on the front (right, light emission side) is 150 μm, a length of the DBR region 441 on the rear (left, light reflection side) is 300 μm, a length of the active region 440 is 400 μm, and a length of a phase adjustment region 446 is 150 μm. Additionally, the phase adjustment region 446 is a region where a phase of light is adjusted to move a ripple in an oscillation spectrum (resonant peak) of an FP laser described later in parallel along a wavelength axis, and phase control is performed based on a voltage applied to an phase adjustment electrode 447.

The DBR laser oscillates because the front and rear DBRs serve as reflection mirrors, and light reciprocating between the DBRs obtains a gain in the active region. Accordingly, when the oscillation mode of the DBR laser is examined, the DBR laser may be considered basically as a Fabry-Perot (FP) laser including regular reflection mirrors on opposite ends.

With the FP laser, of the light reciprocating between the mirrors on opposite ends, oscillation occurs only at a wavelength at which a reciprocating distance between the mirrors is an integral multiple of the wavelength. Accordingly, ripples (resonant peaks) are present at equal intervals in the oscillation spectrum of the FP laser. With the DBR laser, the DBR may be assumed to be a reflection mirror having a certain length of penetration L, and thus, also in the case of the DBR laser, as in the case of the FP laser, oscillation occurs only in a mode in which a reciprocating distance between the mirrors is an integral multiple of the wavelength, and oscillation modes are present at equal intervals in the spectrum.

Below the graphs in FIGS. 12(a) and 12(b), ripples (resonant peaks) of transmission intensity of the FP laser described above are schematically shown, with wavelengths on horizontal axes coinciding those of the upper graphs showing the mirror loss of the DBR lasers, for a case where DBR mirrors on opposite ends of the resonator do not have wavelength dependence.

The DBR laser is different from the FP laser in that the DBRs serving as reflection mirrors have wavelength selectivity. The wavelength selectivity of the DBR is shown in the upper graphs in FIGS. 12(a) and 12(b) as wavelength dependence of the mirror loss of the DBR. Light is more confined in the resonator, the lower the mirror loss, thereby resulting in a condition that facilitates oscillation.

Accordingly, the oscillation mode of the DBR laser is determined by a condition that satisfies both a phase matching condition inside the FP resonator and the wavelength selectivity of the mirror loss of the DBRs. That is, the DBR laser oscillates from a mode with low DBR mirror loss, among modes that satisfy the phase matching condition for the FP resonator.

In the graphs in FIGS. 12(a) and 12(b), oscillation modes that satisfy a condition that the mirror loss on the vertical axis is 50 cm⁻¹ or lower are indicated by black dots •.

In the case where, as shown in FIG. 12(a), the refractive index coupling coefficient κ is 40 cm⁻¹, three black dots are shown, and an oscillation mode at a center with a wavelength of 1550 nm is a condition where mirror loss ath1 is the lowest and oscillation occurs most easily (primary mode).

Furthermore, in FIG. 12(a), a secondary mode where oscillation occurs next easily is present at two wavelengths indicated by black dots • that are, respectively, on a longer wavelength side and a shorter wavelength side of the primary mode at a distance of about 0.5 nm from the primary mode, the mirror loss being ath2 for both cases. A difference between the mirror loss ath1 in the primary mode and the mirror loss ath2 in the secondary mode is about 4.2 cm⁻¹, and operation is performed more in a stable single mode, the greater the mirror loss difference between the primary mode and the secondary mode.

In contrast, a case as shown in FIG. 12(b) where the refractive index coupling coefficient κ is 80 cm⁻¹ is a condition where mirror loss is reduced due to increased Bragg wavelength reflectance of the DBR, light is strongly confined in the resonator, and oscillation occurs easily at a low threshold. Accordingly, in the upper graph in FIG. 12(b), five black dots • are shown, including tertiary modes in addition to the primary mode at the center and the two secondary modes on both sides of the primary mode.

However, a wavelength bandwidth of the mirror loss is also increased, and not only the mirror loss in the primary mode, but also the mirror loss in the secondary mode tends to be reduced. The mirror loss difference between the primary mode and the secondary mode in the case of FIG. 12(b) is about 1.2 cm⁻¹. This mirror loss difference is not enough to achieve a stable single-mode operation.

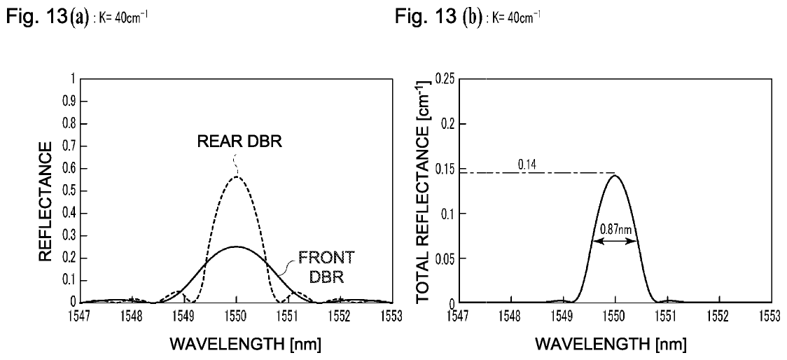

A cause of reduction in the mirror loss difference between the primary mode and the secondary mode in a case where a high refractive index coupling DBR is adopted will be described. FIG. 13(a) shows, in relation to the DBR laser where the front DBR length is 150 μm and the rear DBR length is 300 μm, a reflection spectrum of each of the front and rear DBRs when the refractive index coupling coefficient κ takes a general value of 40 cm⁻¹.

The front DBR has a shorter DBR length than the rear DBR and the front DBR is designed to have lower reflectance than the rear DBR to thereby relatively increase the optical output from the front than from the rear. Oscillation of the DBR laser is caused by confinement of light in the resonator by the front and rear DBRs, and thus, a total reflection spectrum expressed by a product of reflectance of the front DBR and the rear DBR has to be taken into account.

FIG. 13(b) shows the total reflection spectrum calculated from the reflection spectra of the front and rear DBRs in FIG. 13(a). Maximum reflectance of the total reflection spectrum here is 0.14, and a bandwidth where the reflectance is at least half the maximum value (full width at half maximum) is 0.87 nm.

Mirror loss spectra of the DBR lasers shown in FIGS. 12(a) and 12(b) are obtained from such a total reflection spectrum of front and rear DBRs. That is, to cause the DBR laser to operate stably in the single mode, a bandwidth of the total reflection spectrum of the front and rear DBRs shown in FIG. 13(b) has to be narrowed, and the mirror loss difference between the primary oscillation mode and the secondary oscillation mode has to be increased.

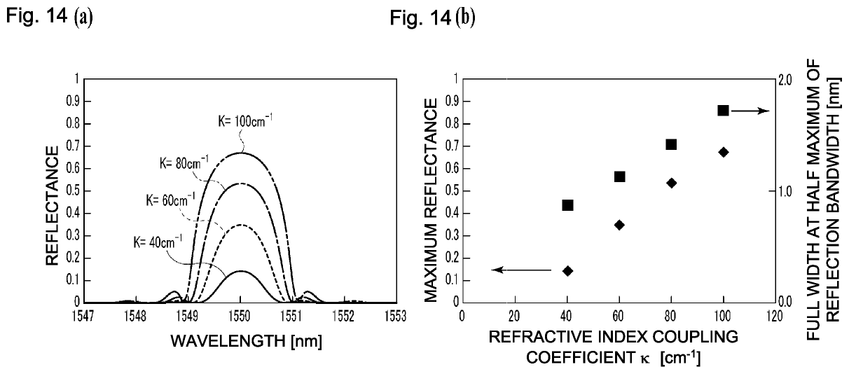

FIG. 14(a) shows, in relation to the DBR laser that uses front and rear DBRs having lengths of 150 μm and 300 μm, respectively, four graphs showing changes in the total reflection spectra for four types of refractive index coupling coefficients κ, the refractive index coupling coefficients κ being 40 cm, 60 cm⁻¹, 80 cm⁻¹, and 100 cm⁻¹.

Furthermore, FIG. 14(b) shows two sets of plots, where the refractive index coupling coefficients κ of the four graphs of the total reflection spectra in FIG. 14(a) are taken as a horizontal axis and maximum reflectance and a reflection spectrum bandwidth (wavelength width where the reflectance is at least half the maximum value) are taken as vertical axes. Black diamonds ♦ plot the maximum reflectance, with the scale on the left vertical axis, and black squares ▪ plot the reflection spectrum bandwidth (full width at half maximum: nm), with the scale on the right vertical axis.

As described above, to obtain high optical feedback resistance, the maximum reflectance has to be increased in the total reflection spectrum, and moreover, to suppress multi-mode oscillation of the DBR laser at the same time, the reflection spectrum bandwidth is desirably narrow and steep.

However, it can be seen from FIGS. 14(a) and 14(b) that, when the refractive index coupling coefficient of the DBRs is great, the maximum reflectance at the Bragg wavelength is increased, and also, the reflectance spectrum bandwidth tends to be increased. For example, as shown in FIG. 14(b), in the case where κ is 40 cm⁻¹, the maximum reflectance is about 14% and the reflection bandwidth (full width at half maximum) is 0.87 nm, but in the case where x is 60 cm⁻¹ the maximum reflectance is 35% and the full width at half maximum is 1.13 nm, and the reflection spectrum bandwidth is increased together with the reflectance.

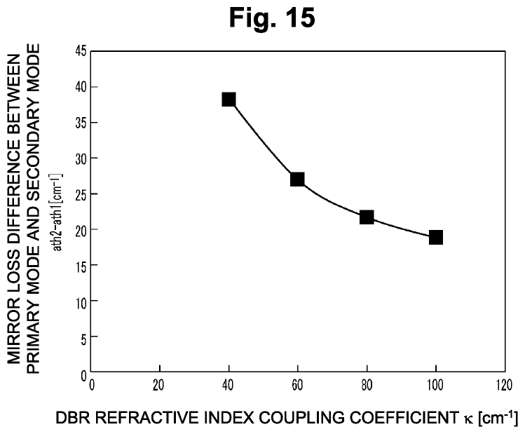

FIG. 15 shows the mirror loss differences (vertical axis) between the primary mode and the secondary mode, where the refractive index coupling coefficient κ (horizontal axis) of the DBR regions of the DBR laser is changed in four ways between 40 cm⁻¹ and 100 cm⁻¹ as in FIG. 14. As is clear from the result, the greater the refractive index coupling coefficient κ, the smaller the mirror loss difference between the primary mode and the secondary mode, thereby being more likely to result in an unstable single-mode operation. This is because, as described above, the bandwidth of the reflection spectrum of the DBR is increased as the refractive index coupling coefficient κ is increased, resulting in a condition where a plurality of oscillation modes are included in the reflection band and oscillation occurs easily.

As a result, in the case where the DBR reflectance is increased to achieve high optical feedback resistance for the DBR laser even at the time of high-output operation, the reflection spectrum bandwidth is inevitably increased, and there is a problem that the possibility of multi-mode operation is increased, and thus, there is a limit to increasing the optical feedback resistance of the SOA-integrated EADBR laser.

### Structure and Operation of SOA-Integrated EADBR Laser of Embodiment 3

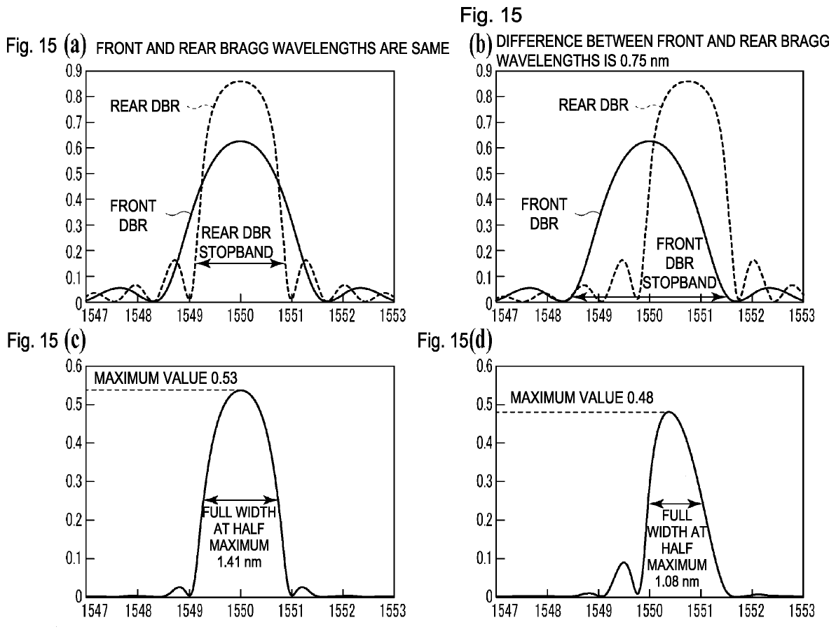

Structure and operation of an optical transmitter according to Embodiment 3 for solving such a problem are described with reference to FIGS. 16 to 18. With the SOA-integrated EADBR laser of Embodiment 3, diffraction gratings with different periods are used in the front DBR and the rear DBR of the DBR laser. This enables a center wavelength (Bragg wavelength) of the reflection band to be shifted (made different) between the front DBR and the rear DBR, and the optical feedback resistance may be increased due to increased reflectance for the front DBR, and also, the total reflection spectrum of the front and rear DBRs may be narrowed, and stability of the single mode may be increased.

FIGS. 16(a) and 16(b) show a reflection spectrum of each of two front and rear DBRs of the DBR laser, for a case where the Bragg wavelengths of the two front and rear DBRs are the same between the front and rear DBRs (FIG. 16(a), comparative example) and for a case where the Bragg wavelengths are different between the two front and rear DBRs (FIG. 16(b), Embodiment 3). FIGS. 16(c) and 16(d) show total reflection spectra corresponding to FIGS. 16(a) and 16(b).

With the two DBR lasers in FIG. 16, the refractive index coupling coefficient κ is 80 cm⁻¹ and is the same for the front and rear DBRs, and region lengths of the front and rear DBRs are 150 μm and 300 μm, respectively. On the other hand, regarding the diffraction grating periods of the two front and rear DBRs, the diffraction grating periods are the same in the comparative example in FIG. 16(a), but in Embodiment 3 in FIG. 16(b), the diffraction grating period of the rear DBR is made greater than that of the front DBR. Alternatively, the diffraction grating period of the rear DBR may be made smaller than the diffraction grating period of the front DBR.

As a result, as shown in FIG. 16(b), the Bragg wavelength of the rear DBR (peak wavelength of dotted line, about 1550.75 nm) is adjusted to be a wavelength that is longer than the Bragg wavelength of the front DBR (peak wavelength of solid line, about 1550 nm) by 0.75 nm. In the case where sizes of the diffraction grating periods of the DBRs are reversed, the Bragg wavelength of the rear DBR is a wavelength that is shorter than the Bragg wavelength of the front DBR.

Furthermore, the Bragg wavelength of the rear DBR (about 1550.75 nm) is adjusted to be within a bandwidth of a stopband of the front DBR (bandwidth indicated by a double-headed arrow in the spectrum indicated by a solid line, about 1548.5 nm to 1551.5 nm).

The total reflection spectra of the comparative example and Embodiment 3, shown in FIGS. 16(c) and 16(d), will be compared. In the case of the DBR laser, for which the diffraction grating periods of the front and rear DBRs are the same, as shown in FIG. 16(c) for the comparative example, the maximum reflectance is 0.53, and the reflection band (full width at half maximum) is 1.41 nm. In contrast, in the case of the DBR laser, for which a difference corresponding to a Bragg wavelength difference of 0.75 nm is present between the diffraction grating periods of the front and rear DBRs, as shown in FIG. 16(d) for Embodiment 3, the maximum reflectance is 0.48, and the reflection band (full width at half maximum) is 1.08 nm.

Compared with the case of the comparative example shown in FIG. 16(c) where the DBRs have the same diffraction grating period, a case of Embodiment 3 shown in FIG. 16(d) where there is a difference between the diffraction grating periods of the front and rear DBRs achieves a narrower and steeper spectrum with respect to the reflection spectrum, albeit with reduced maximum reflectance.

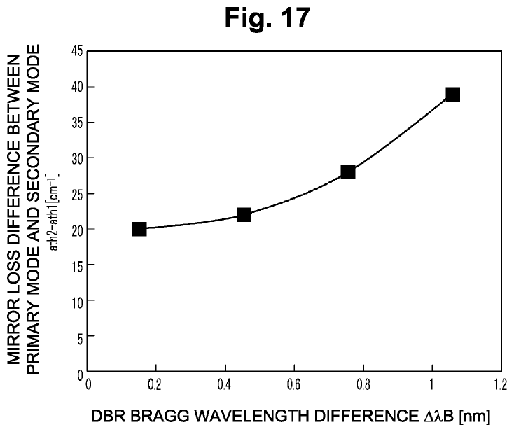

FIG. 17 shows, in relation to the DBR laser of Embodiment 3 where κ is 80 cm⁻¹, the mirror loss difference between modes, in a case where the diffraction grating periods of the front and rear DBRs are changed and the Bragg wavelength difference between the front and rear DBRs is changed. Mirror loss differences between the primary mode and the secondary mode (FIG. 17, vertical axis) are indicated by four black squares ▪ in relation to four values of Bragg wavelength differences AB shown on a horizontal axis in FIG. 17. It can be seen that the mirror loss difference between the primary mode and the secondary mode may be increased by increasing the Bragg wavelength difference, and that a stable single-mode operation may thus be achieved.

Especially when the Bragg wavelength difference is increased in FIG. 17 to about 1.1 nm (rightmost black square ▪ in the graph in FIG. 17) with κ being 80 cm⁻¹, the mirror loss difference between the primary mode and the secondary mode may be increased to close to 40 cm⁻¹. As shown in FIG. 15, this is a mirror loss difference that is about the same as in the case of a general DBR laser where the refractive index coupling coefficient κ is 40 cm⁻¹, and a single mode that is stable enough for practical use may be achieved.

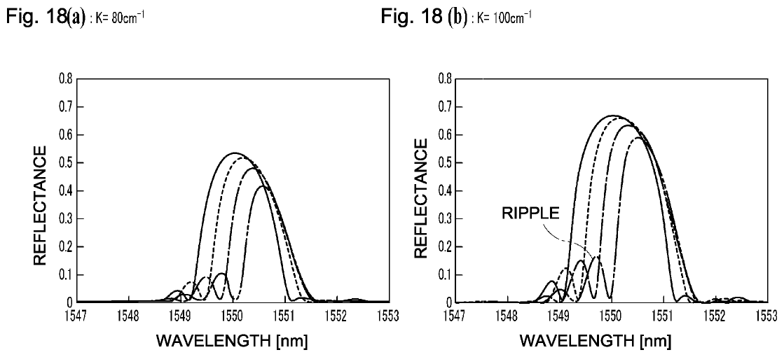

FIG. 18(a) shows a total spectrum of the two front and rear DBRs for a case where the refractive index coupling coefficient κ is 80 cm⁻¹ in Embodiment 3, and FIG. 18(b) shows the total spectrum for a case where the κ is 100 cm⁻¹. Four graphs of the total reflection spectra are shown in each of FIGS. 18(a) and 18(b), where the Bragg wavelength difference between the two front and rear DBRs is changed in four ways between 0.15 nm and 1.1 nm.

As is clear from FIG. 14(a), to achieve the effect of the present invention, the refractive index coupling coefficient should be at least 40 cm⁻¹, and a steeper, higher-reflectance reflection spectrum may be obtained, the greater the refractive index coupling coefficient κ is. However, FIG. 18(b) shows that the greater the refractive index coupling coefficient κ is, the higher the reflectance tends to be for a ripple outside the stopband. This is because a ripple on a short-wave side of the rear DBR moves closer to the Bragg wavelength of the front DBR due to a shift in the Bragg wavelength, resulting in increased reflectance for the ripple, and this becomes more significant, the greater the reflectance of the front DBR is. In the case where the refractive index coupling coefficient is too high, the ripple reflectance is increased outside the stopband, and there is a concern that single mode characteristics deteriorate. Accordingly, the effect of the present invention is best achieved when the refractive index coupling coefficient is 40 cm⁻¹ to 100 cm⁻¹.

As can be understood from FIGS. 16(b) and 16(d), when the Bragg wavelength difference between the front and rear DBRs is increased and there is no overlap between the front and rear reflection spectra, an effect, of the DBR laser, of confinement in the resonator is lost, and oscillation operation cannot be performed. In the case where there is a difference between the Bragg wavelengths of the front and rear DBRs, the maximum reflectance of the total spectrum is rapidly reduced, in relation to the total reflectance, from a point where the Bragg wavelength difference between the front and rear DBRs reaches half the bandwidth of the stopband of the front DBR, or in other words, from a point where the Bragg wavelength of the rear DBR reaches an edge of the stopband of the front DBR. Accordingly, the effect of the present invention is best achieved when the Bragg wavelength difference between the two front and rear DBRs is half or less of the bandwidth of the stopband of the front DBR.

Trial production of the SOA-integrated EADBR laser was performed in view of the above.

### Trial Production and Evaluation of SOA-Integrated EADBR Laser of Embodiment 3

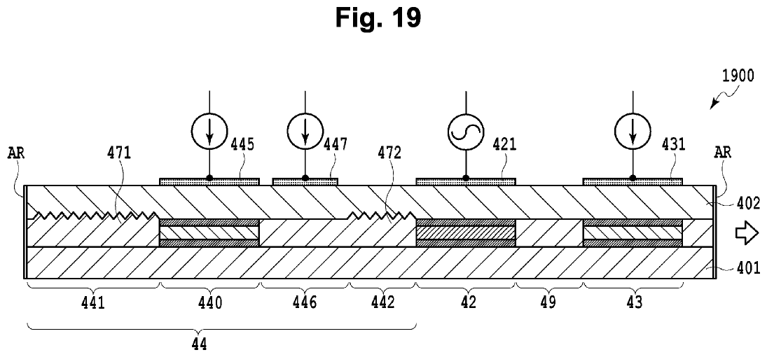

FIG. 19 is a substrate cross-section diagram, along an optical axis, of an SOA-integrated EADBR laser 1900 according to Embodiment 3.

The SOA-integrated EADBR laser 1900 of Embodiment 3 includes the active region 440 having a length of 300 μm, and the DBR laser 44 including the two DBR regions 442, 441 having lengths of 150 μm (front) and 300 μm (rear). The DBR in the DBR region 442 present between the active region 440 and the EA modulator 42 and having a shorter length is the front (first) DBR, and the DBR in the DBR region 441 present on a reflection end face side on a left end and having a longer length is the rear (second) DBR.

Here, in the case where the reflectance of the front and rear DBRs is increased to increase the optical feedback resistance, as in the case of the present invention, light is more strongly confined in the resonator by the front and rear DBRs, and optical output from the front DBR is reduced. By adjusting the front and rear DBR region lengths, and adjusting an optical output ratio between the front and rear, reduction in the optical output from the front may be suppressed. Furthermore, it is also possible to maintain high-output characteristics by increasing the active region length to suppress reduction in the optical output from the front. As described with reference to FIG. 12(c), the phase adjustment region 446 and the phase adjustment electrode 447 may be provided also in the DBR laser 44 of Embodiment 3.

Furthermore, as in Embodiment 1 (FIGS. 4 to 8), the EA modulator 42 having a length of 150 μm, the passive waveguide 49 having a length of 50 μm, and the SOA 43 having a length of 200 μm are integrated in front of the DBR laser 44 to form a monolithically integrated element as a whole.

In Embodiment 3, the diffraction grating period of the front DBR 442 is 240.000 nm, and the diffraction grating period of the rear DBR 441 is 240.183 nm, and the difference between the Bragg wavelengths of the front and rear DBRs is designed to be about 1.2 nm. The bandwidth of the total reflection spectrum of the two front and rear DBRs may thereby be narrowed, and single mode stability may be increased. Moreover, the refractive index coupling coefficient is 80 cm⁻¹ for the front and rear DBRS.

A fabrication process of the SOA-integrated EADBR laser 1900 of Embodiment 3 is the same as the process described in Embodiment 1. However, at the time of forming diffraction grating structures of the DBRs after butt-joint growth of the respective regions, DBR patterns with periods that are different between front and rear diffraction gratings, as described above, are formed.

Generally, a diffraction grating of a DBR laser is formed by etching a semiconductor layer, and diffraction gratings of front and rear DBRs are collectively formed in the same process, and thus, depths of the front and rear diffraction gratings cannot be adjusted separately. Accordingly, the refractive index coupling coefficient κ takes the same value for the front and rear DBRs.

On the other hand, the diffraction grating period may be formed to be of any period by pattern drawing of the diffraction grating, and thus, diffraction grating periods that are different between the front and rear DBRs may easily be introduced. Also with the element fabricated for trial in Embodiment 3, two DBRs with different diffraction grating periods may be fabricated simply by changing a drawing pattern, and fabrication steps and cost do not have to be changed at all.

Moreover, as Comparative Example 1 for checking the effect of the present embodiment, an SOA-integrated EADBR laser where the front and rear DBRs have the same diffraction grating period was fabricated on the same substrate. Each region length, the refractive index coupling coefficient and the like are the same as those of the device according to Embodiment 3.

Oscillation spectra were checked for the two SOA-integrated EADBR lasers fabricated in the above manner. Drive currents of 80 mA, 40 mA were injected in the active regions of the DBR lasers and the SOA regions, respectively.

With the element according to Embodiment 3, where a Bragg wavelength difference is present between the front and rear DBRs, stable single-mode operation was achieved, and an SMSR was confirmed to be 45 dB in the primary mode and the secondary mode. On the other hand, with the element of Comparative Example 1 where the diffraction grating periods are the same for the front and rear DBRs, oscillation in the multi-mode was confirmed, and application as a light source for optical fiber transmission was difficult. As a result, it is confirmed that, in the case where diffraction gratings with the same period are used in the front and rear DBRs, stable operation in the single mode is difficult unless a relatively small refractive index coupling coefficient is used.

Moreover, to further confirm superiority of Embodiment 3, an SOA-integrated EADBR laser that uses a general refractive index coupling coefficient of 40 cm⁻¹ and that uses DBRs with the same diffraction grating period for the front and rear DBRs was fabricated as Comparative Example 2, and comparison of transmission characteristics was performed using the same.

Also with the element of Comparative Example 2 where x is 40 cm⁻¹, the front and rear DBR lengths, the active region length, the EA modulator length, and the SOA length are same as those of the element of Embodiment 3. Comparison of optical output intensity was conducted, with a DBR laser drive current being 120 mA and an SOA drive current being 80 mA for both devices.

It was then confirmed that, in the case of the element of Comparative Example 2 where κ is 40 cm⁻¹, the optical output intensity was 13.5 dBm, but in the case of the element of Embodiment 3 where there is a Bragg wavelength difference and κ is 80 cm⁻¹, the optical output intensity was 12 dBm. The output of the element according to Embodiment 3 is slightly smaller due to reduction in the optical output from the front caused by an increase in diffraction grating reflectance.

Modulation characteristics at 10 Gbit/s was evaluated under such operation conditions. When a mask test was conducted for an eye pattern at 10 Gbit/s, the element of Comparative Example 2 where κ is 40 cm⁻¹ did not pass the mask test. On the other hand, in the case of the element of Embodiment 3 with a Bragg wavelength difference and where x is 80 cm⁻¹, a clear eye opening was confirmed, and the mask test was confirmed to be passed with a mask margin of 10%. That is, at the time of high-output operation exceeding 10 dBm, the optical feedback is greatly increased, and operation tends to be unstable also with a DBR laser having higher optical feedback resistance than a DFB laser. However, the optical feedback resistance may be further increased by increasing κ of the DBR laser.

Lastly, evaluation of optical fiber transmission characteristics at 10 Gbit/s was conducted. As a modulation signal, an NRZ pseudo-random signal (PRBS) at 2³¹−1 stage cycle was used, and a bias voltage to the EA modulator was 1.5 V, and an amplitude voltage was 2.0 V. When evaluation of a bit error rate for transmission over 40 km was conducted, the element of Comparative Example 2 where κ is 40 cm⁻¹ could not achieve error-free operation. On the other hand, with the element of Embodiment 3 where κ is 80 cm⁻¹ and there is a Bragg wavelength difference between the front and rear DBRs, error-free operation up to bit error rate 10⁻¹² was confirmed, and sufficient characteristics as a light source for optical fiber transmission were obtained.

### INDUSTRIAL APPLICABILITY

As described above, the present invention is capable of providing an optical transmitter having high optical feedback resistance even at the time of high-output operation and capable of suppressing deterioration of optical waveform quality and transmission characteristics, and of providing an optical transmitter with which uniform optical output intensity may be achieved in relation to an arrayed multi-wavelength light source.

### REFERENCE SIGNS LIST

10 EADFB laser
11, 31 DFB laser
12, 32, 42 EA modulator
14, 34, 36, 440 active layer (active region)
15, 35 light absorption layer
17, 471, 472 diffraction grating
30 SOA-integrated EADFB laser
33, 43 SOA
400, 600, 700, 800, 1900 SOA-integrated EADBR laser
401 n-InP substrate
402 p-InP cladding layer
44 DBR laser
441, 442 DBR region
446 phase adjustment region
421, 431, 443, 444, 445, 447, 491 electrode
49 passive waveguide
91 multiplexer

1. An optical transmitter, comprising:
a DBR laser including an active region where current is injected and optical gain is obtained, and two DBR regions that are formed on opposite ends of the active region;
an EA modulator optically modulating laser light from the DBR laser; and
an SOA optically amplifying modulated light from the EA modulator,
wherein the DBR laser, the EA modulator, and the SOA are monolithically integrated on a same substrate.

2. The optical transmitter according to claim 1, wherein a passive optical waveguide for guiding the modulated light from the EA modulator is provided between the EA modulator and the SOA.

3. The optical transmitter according to claim 2, wherein an electrode is formed on the passive optical waveguide, the electrode being for monitoring the modulated light guided in the passive optical waveguide.

4. The optical transmitter according to claim 1, wherein current is injected into the active region of the DBR laser and the SOA by a same control terminal.

5. The optical transmitter according to claim 1, wherein electrodes are formed on the two DBR regions, and the electrodes are grounded.

6. A multi-wavelength optical transmitter comprising:
a plurality of optical transmitters according to claim 1, the plurality of optical transmitters having different oscillation wavelengths; and
a multiplexer for multiplexing output light from the optical transmitters, wherein
intensity of output light of all the optical transmitters are made uniform by making a length of at least one of the active region and the SOA of at least one of the plurality of optical transmitters on a short-wavelength side longer than those of other optical transmitters.

7. A multi-wavelength optical transmitter comprising:
a plurality of optical transmitters according to claim 1, the plurality of optical transmitters having different oscillation wavelengths; and
a multiplexer for multiplexing output light from the optical transmitters, wherein
intensity of output light of all the optical transmitters are made uniform by making a front-rear ratio of lengths of the two DBR regions of at least one of the plurality of optical transmitters on a short-wavelength side smaller than those of other optical transmitters.

8. The optical transmitter according to claim 1, wherein diffraction grating periods of the two DBR regions included in the DBR laser are different from each other.

9. The optical transmitter according to claim 8, wherein
diffraction gratings of the two DBR regions included in the DBR laser have a same refractive index coupling coefficient, and
the refractive index coupling coefficient takes a value in a range of 40 cm⁻¹ to 100 cm⁻¹.

10. The optical transmitter according to claim 9, wherein,
when, of DBRs of the two DBR regions, a DBR present between the active region of the DBR laser and the EA modulator is taken as a first DBR, and another DBR is taken as a second DBR,
a wavelength difference between a Bragg wavelength of the first DBR and a Bragg wavelength of the second DBR is half or less of a bandwidth of a stopband of the first DBR.
